(19) United States
(12) Patent Application Publication
(10) Pub. No.: US 2026/0057915 A1
(43) Pub. Date: Feb. 26, 2026

(54) MEMORY DEVICE

(71) Applicant: Kioxia Corporation, Tokyo (JP)

(72) Inventors: Shogo ITAI, Yokohama Kanagawa (JP); Masahiko NAKAYAMA, Yokohama Kanagawa (JP)

(73) Assignee: Kioxia Corporation, Tokyo (JP)

(21) Appl. No.: 19/040,136

(22) Filed: Jan. 29, 2025

(30) Foreign Application Priority Data
Aug. 23, 2024 (JP) 2024-141990

(51) Int. Cl. G11C 5/08; G11C 11/16

(52) U.S. Cl. CPC G11C 5/08; G11C 11/1673; G11C 11/1675

(57) ABSTRACT

An operation of bringing a magnetoresistance effect element into a first resistance state includes a first period, a second period, a third period, a fourth period, and a fifth period. In the first period, a first operation is performed to bring the magnetoresistance effect element into a second resistance state exhibiting a resistance that is lower than a resistance of the first resistance state. In the second period, first data is acquired based on a resistance state of the magnetoresistance effect element. In the third period, a second operation is performed to bring the magnetoresistance effect element into the first resistance state. In the fourth period, second data is acquired based on the resistance state of the magnetoresistance effect element. In the fifth period, a third operation is performed to bring the magnetoresistance effect element into the first resistance state.

### CROSS-REFERENCE TO RELATED APPLICATION

This application is based upon and claims the benefit of priority from Japanese Patent Application No. 2024-141990, filed Aug. 23, 2024, the entire contents of which are incorporated herein by reference.

### FIELD

Examples of a memory device includes a magnetic memory device.

### BACKGROUND

A memory device using a magnetoresistance effect element is known. The memory device is required to have a long lifetime.

### BRIEF DESCRIPTION OF THE DRAWINGS

FIG. 1 illustrates functional blocks of a memory device of a first embodiment.

FIG. 2 is a circuit diagram of a memory cell array of the memory device of the first embodiment.

FIG. 3 is a perspective view of a part of the memory cell array of the memory device of the first embodiment.

FIG. 4 illustrates a cross section of an example of a structure of a memory cell of the memory device of the first embodiment.

FIG. 5 illustrates an example of voltage and current characteristics of the memory cell of the memory device of the first embodiment.

FIG. 6 illustrates functional blocks and components of a part of the memory device of the first embodiment.

FIG. 7 illustrates an example of components of a read circuit of the memory device and coupling of the components of the first embodiment.

FIG. 8 illustrates an example of components of a write circuit of the memory device and coupling of the components of the first embodiment.

FIG. 9 illustrates a flow of data write to the memory device of the first embodiment.

FIG. 10 illustrates an example of the magnitude of current flowing through a memory cell during AP write to the memory device of the first embodiment along the time axis.

FIG. 11 illustrates an example of components and coupling of the components of a read circuit of a memory device of a second embodiment.

FIG. 12 illustrates a first example of components and the coupling of the components of a current regulation circuit of the memory device of the second embodiment.

FIG. 13 illustrates a second example of the components and the coupling of the components of the current regulation circuit of the memory device of the second embodiment.

FIG. 14 illustrates the potentials of some nodes along the time axis during data read from the memory device of the second embodiment.

FIG. 15 illustrates a flow of data write to the memory device of the second embodiment.

FIG. 16 illustrates an example of the magnitude of current flowing through a memory cell during AP write to the memory device of the second embodiment along the time axis.

### DETAILED DESCRIPTION

In general, according to one embodiment, a memory device includes a memory cell, a first, and a second interconnect. The memory cell includes a magnetoresistance effect element and a switching element coupled to the magnetoresistance effect element. The first interconnect is coupled to a first end of the memory cell. The second interconnect is coupled to a second end of the memory cell. An operation of bringing the magnetoresistance effect element into a first resistance state includes a first period, a second period after the first period, a third period after the second period, a fourth period after the third period, and a fifth period after the fourth period. In the first period, a first operation is performed to bring the magnetoresistance effect element into a second resistance state exhibiting a resistance that is lower than a resistance of the first resistance state. In the second period, first data is acquired based on a resistance state of the magnetoresistance effect element. In the third period, a second operation is performed to bring the magnetoresistance effect element into the first resistance state. In the fourth period, second data is acquired based on the resistance state of the magnetoresistance effect element. In the fifth period, a third operation is performed to bring the magnetoresistance effect element into the first resistance state.

Embodiments will now be described with reference to the figures. In order to distinguish components having substantially the same function and configuration in an embodiment or over different embodiments from each other, an additional numeral or letter may be added to the end of each reference numeral or letter. For an embodiment subsequent to an embodiment that has already been described, the description will concentrate mainly on the matters that constitute a difference from the already described embodiment. The entire description of a particular embodiment applies to another embodiment unless an explicit mention is made otherwise, or an obvious elimination is involved.

Some of the functions may be implemented by functional blocks different from those illustrated below. Furthermore, an illustrated functional block may be divided into functional sub-blocks.

The specification and the claims, when mentioning that a particular (first) component is “coupled” to another (second) component, intend to cover both the form of the first component directly coupled to the second component and the form of the first component coupled to the second component via one or more components which are always or selectively conductive.

Hereinafter, embodiments will be described using a three-dimensional orthogonal coordinate system. A direction of an x axis is referred to as an X direction. A direction opposite to the X direction is referred to as a-X direction. A direction of a y axis is referred to as a Y direction. A direction opposite to the Y direction is referred to as a-Y direction. A direction of a z axis is referred to as a Z direction, and up indicates the Z direction. A direction opposite to the Z direction is referred to as a-Z direction.

### 1. First Embodiment

### 1.1. Configuration (Structure)

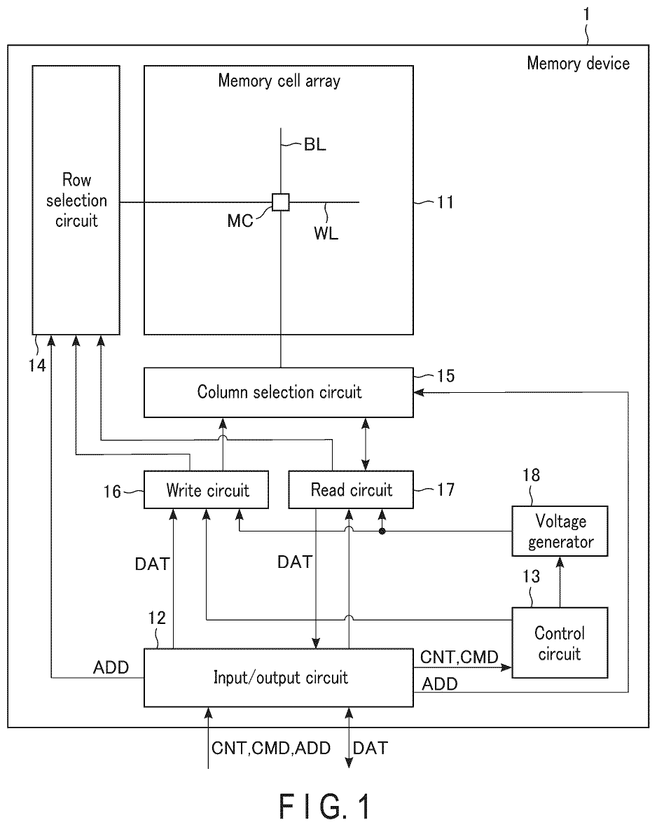

FIG. 1 illustrates functional blocks of a memory device in a first embodiment. A memory device 1 is a device that stores data. The memory device 1 is a magnetic memory device that stores data using a layer stack of magnetic bodies exhibiting variable resistance. As illustrated in FIG. 1, the memory device 1 includes a memory cell array 11, an input/output circuit 12, a control circuit 13, a row selection circuit 14, a column selection circuit 15, a write circuit 16, a read circuit 17, and a voltage generator 18.

The memory cell array 11 is a set of arrayed memory cells MC. The memory cells MC can store data in a nonvolatile manner. A plurality of word lines WL and a plurality of bit lines BL are located in the memory cell array 11. Each memory cell MC is coupled to a single word line WL and a single bit line BL. The word lines WL are associated with rows. The bit lines BL are associated with columns. One memory cell MC is specified by selection of a single row and selection of a single column.

The input/output circuit 12 is a circuit that inputs and outputs data and signals. The input/output circuit 12 receives a control signal CNT, a command CMD, address information ADD, and data DAT from the outside of the memory device 1, or, in one example, from a memory controller. The input/output circuit 12 outputs the data DAT. The data DAT is write data in the case of data writing into the memory device 1. The data DAT is read data in the case of data reading from the memory device 1.

The voltage generator 18 is a circuit that generates voltages of various magnitudes from voltages received from the outside of the memory device 1. The voltages received from the outside include a power supply voltage VDD and a ground voltage VSS. The voltage generator 18 outputs a voltage of constant magnitude used for data reading. The voltage generator 18 outputs a voltage of constant magnitude used for data writing.

The write circuit 16 is a circuit that controls writing of data in the memory cell MC. The write circuit 16 receives the write data DAT from the input/output circuit 12 and receives the voltage for data writing from the voltage generator 18. The write circuit 16 outputs, based on control of the control circuit 13 and the write data DAT, a voltage and a current used for data writing.

The read circuit 17 is a circuit that controls reading of data from the memory cell MC. The read circuit 17 receives the voltage for data reading from the voltage generator 18. The read circuit 17 determines what data is stored in the memory cell MC using the voltage for data reading based on the control of the control circuit 13. The determined data is supplied to the input/output circuit 12 as read data DAT. The read circuit 17 includes a sense amplifier.

The row selection circuit 14 is a circuit that selects a row of the memory cell MC. The row selection circuit 14 receives the address information ADD from the input/output circuit 12. The row selection circuit 14 receives the voltage for data writing from the write circuit 16. The row selection circuit 14 receives the voltage for reading data from the read circuit 17. The row selection circuit 14 uses the voltage for data writing during data writing to select one or more word lines WL associated with a row specified by the received address information ADD. During data reading, the row selection circuit 14 uses the voltage for data reading to select one or more word lines WL associated with the row specified by the received address information ADD.

The column selection circuit 15 is a circuit that selects a column of the memory cell MC. The column selection circuit 15 receives the address information ADD from the input/output circuit 12. The column selection circuit 15 receives the voltage for data writing from the write circuit 16. The column selection circuit 15 receives the voltage for data reading from the read circuit 17. During data writing, the column selection circuit 15 uses the voltage for data writing to select one or more bit lines BL associated with a column specified by the received address information ADD. During data reading, the column selection circuit 15 uses the voltage for data reading to select the one or more bit lines BL associated with the column specified by the received address information ADD.

The control circuit 13 is a circuit that controls the operation of the memory device 1. The control circuit 13 receives the control signal CNT and the command CMD from the input/output circuit 12. The control circuit 13 controls the write circuit 16 and the read circuit 17 based on control instructed by the control signal CNT and the command CMD. Specifically, the control circuit 13 controls the write circuit 16 to supply the voltage received by the write circuit 16 from the voltage generator 18 to the row selection circuit 14 and the column selection circuit 15 during writing of data in the memory cell MC. The control circuit 13 controls the read circuit 17 to supply the voltage received by the read circuit 17 from the voltage generator 18 to the row selection circuit 14 and the column selection circuit 15 during reading of data from the memory cell MC.

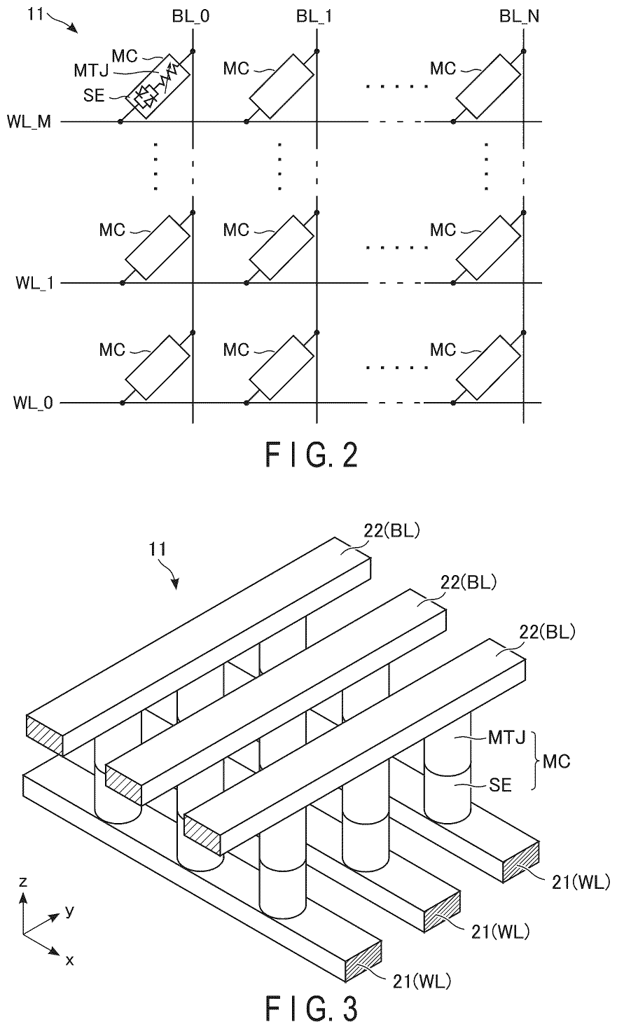

FIG. 2 is a circuit diagram of a memory cell array of the memory device in the first embodiment. As illustrated in FIG. 2, M+1 (M being a positive integer) word lines WL (WL_0, WL_1, . . . , WL_M) and N+1 (N being a positive integer) bit lines BL (BL_0, BL_1, . . . , BL_N) are located in the memory cell array 11.

Each memory cell MC is coupled to a single word line WL and a single bit line BL. Each memory cell MC includes a single MTJ element MTJ and a single switching element SE. In each memory cell MC, the MTJ element MTJ and the switching element SE are coupled in series. The switching element SE of each memory cell MC is coupled to a single word line WL. The MTJ element MTJ of each memory cell MC is coupled to a single bit line BL.

The MTJ element MTJ exhibits a tunnel magnetoresistance effect, and for example, is an element including a magnetic tunnel junction (MTJ). The MTJ element MTJ is also referred to as a magnetoresistance effect element MTJ. The MTJ element MTJ is a variable resistance element that can switch between a low resistance state and a high resistance state. The MTJ element MTJ can store 1-bit data using a difference between the two resistance states. In one example, the MTJ element MTJ stores “0” data according to the low resistance state and “1” data according to the high resistance state. The following description is based on this example.

The switching element SE is an element that electrically couples or uncouples both terminals of the switching element SE. The switching element SE has two terminals. While a voltage applied between the two terminals in a first direction is lower than a first threshold, the switching element SE is in a high resistance state, for example, an electrically non-conductive state (OFF state). When the voltage applied between the two terminals rises to be equal to or higher than the first threshold, the switching element SE enters a low resistance state, for example, an electrically conductive state (ON state). When the voltage applied between the two terminals of the switching element SE in the low resistance state drops to be equal to or lower than a second threshold, the switching element SE enters the high resistance state. The switching element SE has the same function as the function of switching between the high resistance state and the low resistance state based on the magnitude of the voltage applied in the first direction in a second direction opposite to the first direction. That is, the switching element SE is a bidirectional switching element. With the ON or OFF state of the switching element SE, the presence or absence of supply of a current to the MTJ element MTJ coupled to the switching element SE, that is, selection or non-selection of the MTJ element MTJ, can be controlled.

FIG. 3 is a perspective view of a part of the memory cell array of the memory device of the first embodiment. As illustrated in FIG. 3, a plurality of conductors 21 and a plurality of conductors 22 are provided.

The conductors 21 each have a linear shape, extend in the X direction, and are aligned in the Y direction. Each conductor 21 functions as a single word line WL.

The conductors 22 are located farther in the Z direction than the conductors 21. The conductors 22 each have a linear shape, extend in the Y direction, and are aligned in the X direction. Each conductor 22 functions as a single bit line BL.

A single memory cell MC is provided at each of the intersections of the conductors 21 and the conductors 22. Each memory cell MC includes a structure functioning as the switching element SE and a structure functioning as the MTJ element MTJ. Each of the structure functioning as the switching element SE and the structure functioning as the MTJ element MTJ includes one or more layers. In one example, the structure functioning as the MTJ element MTJ is located on an upper surface of the structure functioning as the switching element SE. A lower surface of the memory cell MC is in contact with an upper surface of a single conductor 21. An upper surface of the memory cell MC is in contact with a lower surface of a single conductor 22.

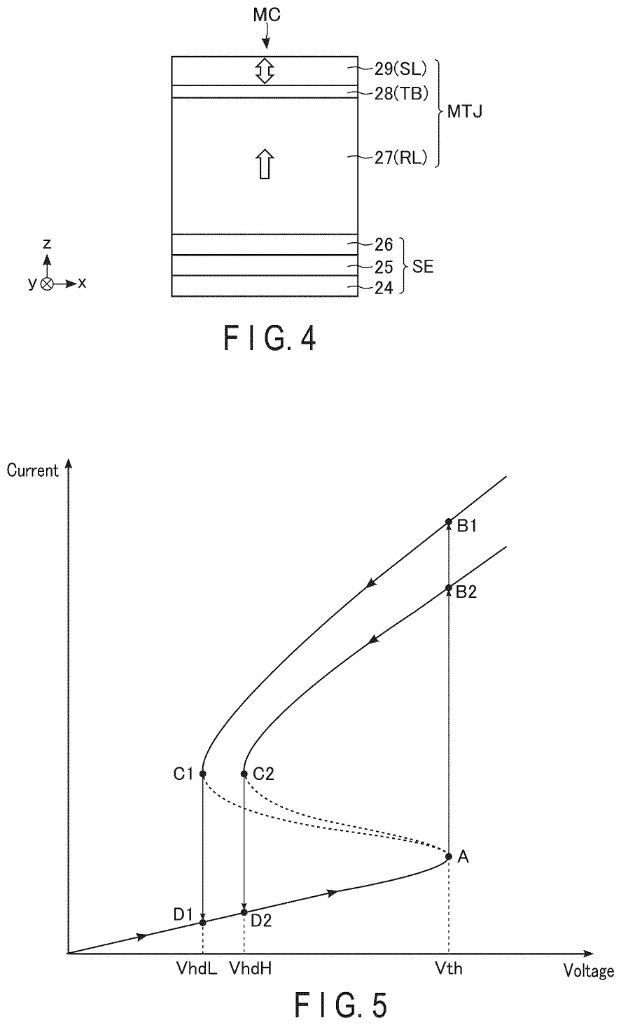

FIG. 4 illustrates a cross section of an example of the structure of the memory cell of the memory device of the first embodiment. As illustrated in FIG. 4, the switching element SE includes a variable resistance material 25. The variable resistance material 25 is a material exhibiting dynamically variable resistance, and, in one example, has a layer shape. The variable resistance material 25 is a switching element between its two terminals where a first terminal of the two terminals is one of the upper surface and the lower surface of the variable resistance material 25, and a second terminal of the two terminals is the other of the upper surface and the lower surface of the variable resistance material 25. While a voltage applied between the two terminals is lower than a first threshold (threshold voltage Vth), the variable resistance material 25 is in a “high resistance” state, for example, an electrically non-conductive state. When the voltage applied between the two terminals rises to be equal to or higher than the first threshold, the variable resistance material enters a “low resistance” state, for example, an electrically conductive state. When the voltage applied between the two terminals of the variable resistance material 25 in the low resistance state drops to be equal to or lower than a second threshold, the variable resistance material enters the high resistance state.

The variable resistance material 25 includes an insulator and a dopant introduced into the insulator by ion implantation. The insulator includes, for example, an oxide, SiO₂, or a material consisting substantially of SiO₂. In one example, the dopant includes arsenic (As) and germanium (Ge). In the first embodiment, the variable resistance material 25 has been described as one including the foregoing composition, but the material is not limited to that composition. The description “consisting (or formed) substantially of” and similar terms are meant to permit a component “consisting substantially of” something to contain unintended impurities.

The switching element SE can further include a lower electrode 24 and an upper electrode 26. FIG. 4 illustrates such an example. The variable resistance material 25 is located on an upper surface of the lower electrode 24, and the upper electrode 26 is located on an upper surface of the variable resistance material 25.

The MTJ element MTJ includes a ferromagnetic layer 27, an insulating layer 28, and a ferromagnetic layer 29. As an example, as illustrated in FIG. 4, the insulating layer 28 is located on an upper surface of the ferromagnetic layer 27, and the ferromagnetic layer 29 is located on an upper surface of the insulating layer 28.

The ferromagnetic layer 27 is a layer of a material exhibiting ferromagnetism. The ferromagnetic layer 27 has an easy magnetization axis in a direction piercing through interfaces among the ferromagnetic layer 27, the insulating layer 28, and the ferromagnetic layer 29, at an angle of 45° through 90° to the interfaces in one example, or in a direction orthogonal to the interfaces in one example. A magnetization direction of the ferromagnetic layer 27 is intended to be unchanged even by reading and writing of data in the memory cell MC. The ferromagnetic layer 27 can function as a so-called reference layer (RL). The ferromagnetic layer 27 may include a plurality of layers. Hereinafter, the ferromagnetic layer 27 may be referred to as reference layer 27.

The insulating layer 28 is a layer of an insulator. The insulating layer 28 includes or consists substantially of, for example, magnesium oxide (MgO) and functions as a so-called tunnel barrier (TB).

The ferromagnetic layer 29 is a layer of a material exhibiting ferromagnetism. The ferromagnetic layer 29 includes or consists substantially of, for example, cobalt iron boron (CoFeB) or iron boride (FeB). The ferromagnetic layer 29 has an easy magnetization axis in a direction piercing through interfaces among the ferromagnetic layer 27, the insulating layer 28, and the ferromagnetic layer 29, at an angle of 45° through 90° to the interfaces in one example, or in a direction orthogonal to the interfaces in one example. A magnetization direction of the ferromagnetic layer 29 is made to be variable by data writing to the memory cell MC, and the ferromagnetic layer 29 can function as a so-called storage layer (SL). Hereinafter, the ferromagnetic layer 29 may be referred to as storage layer 29.

When the magnetization direction of the storage layer 29 is parallel to the magnetization direction of the reference layer 27, the MTJ element MTJ has a certain low resistance. When the magnetization direction of the storage layer 29 is antiparallel to the magnetization direction of the reference layer 27, the MTJ element MTJ has a resistance higher than a resistance in the case in which the magnetization direction of the storage layer 29 and the magnetization direction of the reference layer 27 are antiparallel. Hereinafter, the state in which the magnetization direction of the ferromagnetic layer 29 of an MTJ element MTJ is parallel to that of the reference layer 27 may be referred to as the MTJ element MTJ “in a parallel state” or “in a P state.” The state in which the magnetization direction of the ferromagnetic layer 29 of an MTJ element MTJ is antiparallel to that of the reference layer 27 may be referred to as the MTJ element MTJ “in an antiparallel state” or “in an AP state.”

When a current having a magnitude equal to or larger than a magnitude of a current Icp flows from the storage layer 29 toward the reference layer 27, the magnetization direction of the storage layer 29 becomes parallel to the magnetization direction of the reference layer 27. The operation of bringing the MTJ element MTJ into the parallel state may be referred to as P write. The reversal of the magnetization direction is a phenomenon depending upon probability. In one example, therefore, a P write current Iwp that is larger than the current Icp may flow through the MTJ element MTJ in order to provide a margin and bring the MTJ element MTJ into a parallel state. The P write current Iwp is larger than a read current Ir. Since the reversal of magnetization is a phenomenon depending upon probability, even if a current that is smaller than the P write current Iwp is caused to flow from the storage layer 29 toward the reference layer 27, the MTJ element MTJ may be brought into a parallel state from the anti-parallel state.

When a current having another magnitude equal to or larger than a magnitude of a current Icap flows from the reference layer 27 toward the storage layer 29, the magnetization direction of the storage layer 29 becomes antiparallel to the magnetization direction of the reference layer 27. The operation of bringing the MTJ element MTJ into the antiparallel state may be referred to as AP write. As in the P write, in one example, an AP write current Iwap that is larger than the current Icap is caused to flow through the MTJ element MTJ in order to provide a margin and bring the MTJ element MTJ into an anti-parallel state. The AP write current Iwap is larger than the P write current Iwp. Since the reversal of magnetization is a phenomenon depending upon probability, even if a current that is smaller than the AP write current Iwap is caused to flow from the reference layer 27 toward the storage layer 29, the MTJ element MTJ may be brought into an anti-parallel state from the parallel state.

The MTJ element MTJ may include further layers.

FIG. 5 illustrates an example of voltage and current characteristics of the memory cell of the memory device of the first embodiment. The horizontal axis of a graph indicates the magnitude of a terminal voltage (that is, a difference in potential between both terminals) of the memory cell MC. The vertical axis of the graph indicates, in a logarithmic scale, the magnitude of a current flowing through the memory cell MC. In FIG. 5, virtual characteristics that do not actually appear are indicated by broken lines. FIG. 5 illustrates a case in which the memory cell MC is in the low resistance state and a case in which the memory cell MC is in the high resistance state.

When the voltage is increased from 0, the current keeps increasing until it reaches a threshold voltage Vth. Until the voltage reaches the threshold voltage Vth, the switching element SE of the memory cell MC is off, that is, is non-conductive.

When the voltage is further increased and the voltage reaches the threshold voltage Vth, that is, reaches a point A, a relation between the voltage and the current shows a discontinuous change and shows characteristics shown at points B1 and B2. The magnitude of the current at the points B1 and B2 is significantly larger than the magnitude of the current at the point A. This rapid change in the current is based on the switching element SE of the memory cell MC being turned on. The magnitude of the current at the points B1 and B2 depends on a resistance state of the MTJ element MTJ of the memory cell MC.

When the voltage is reduced from the state in which the switching element SE is on, for example a state in which the voltage and the current indicate a relation shown at the point B1 or B2 and points having a higher voltage than the point B1 or B2, the current keeps decreasing.

When the voltage is further reduced and reaches a certain magnitude, the relation between the voltage and the current shows a discontinuous change. The voltage when the relation between the voltage and the current starts to show discontinuity depends on the terminal voltage of the MTJ element MTJ of the memory cell MC, that is, depends on whether the MTJ element MTJ is in the high resistance state or the low resistance state. When the MTJ element MTJ is in the low resistance state, the relation between the voltage and the current shows discontinuity from a point C1. When the MTJ element MTJ is in the high resistance state, the relation between the voltage and the current shows discontinuity from a point C2. When the voltage reaches the points C1 and C2, the relation between the voltage and the current shows characteristics shown at points D1 and D2. The magnitudes of the currents at the points D1 and D2 are respectively significantly smaller than the magnitudes of the currents at the points C1 and C2. This rapid change in the current is based on the switching element SE of the memory cell MC being turned off.

The terminal voltage at the point D1 of the memory cell MC including the MTJ element MTJ in the low resistance state is referred to as low hold voltage VhdL. The terminal voltage at the point D2 of the memory cell MC including the MTJ element MTJ in the high resistance state is referred to as high hold voltage VhdH.

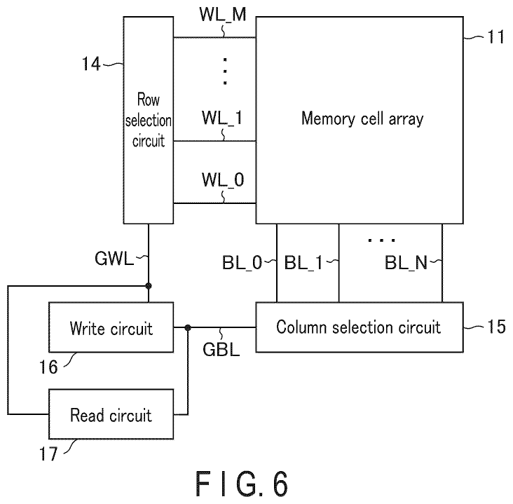

FIG. 6 illustrates functional blocks and components of a part of the memory device of the first embodiment. As illustrated in FIG. 6, the write circuit 16 is coupled to a global word line GWL and a global bit line GBL. The read circuit 17 is coupled to the global word line GWL and the global bit line GBL.

The global word line GWL is coupled to the row selection circuit 14. The row selection circuit 14 connects the global word line GWL to one word line WL specified by the address information ADD.

The global bit line GBL is coupled to the column selection circuit 15. The column selection circuit 15 connects the global bit line GBL to a single bit line BL specified by the address information ADD.

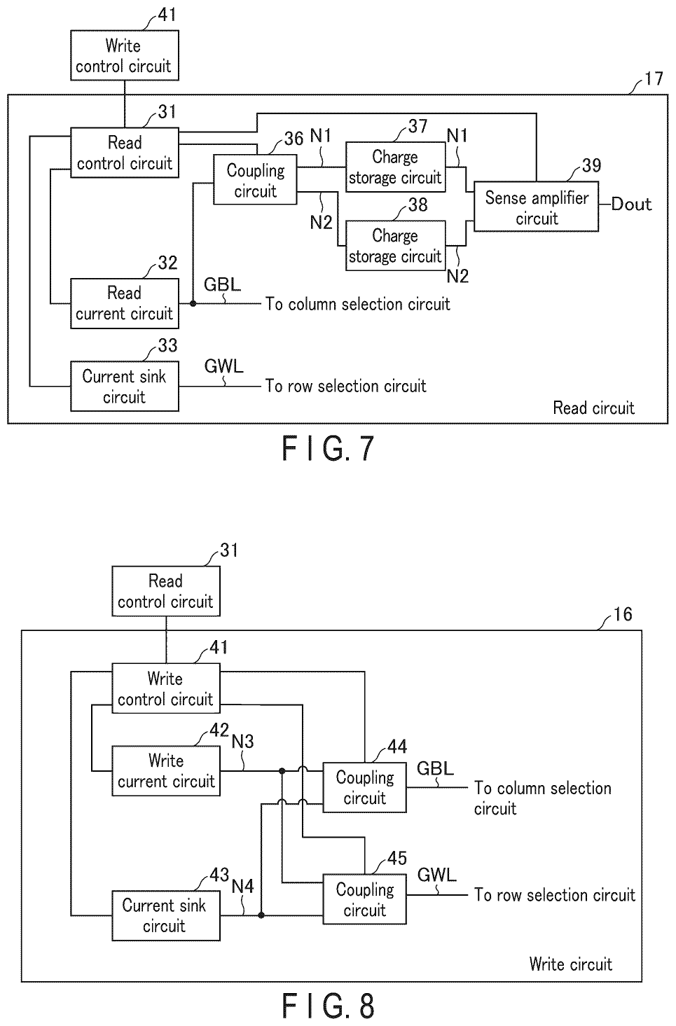

FIG. 7 illustrates an example of components and coupling of the components of the read circuit of the memory device of the first embodiment. As illustrated in FIG. 7, the read circuit 17 includes a read control circuit 31, a read current circuit 32, a current sink circuit 33, a coupling circuit 36, charge storage circuits 37 and 38, and a sense amplifier circuit 39.

The read current circuit 32 is a circuit that supplies a current to a current path including an interconnect coupled to the read current circuit 32. The read current circuit 32 is coupled to the global bit line GBL to allow a read current Ir of a fixed magnitude to be supplied to a current path including the global bit line GBL. The read current circuit 32 operates under the control of the read control circuit 31, and is enabled or disabled under the control of the read control circuit 31. The read current circuit 32 supplies the read current Ir to the global bit line GBL over a dynamically variable period under the control of the read control circuit 31. In one example, the read current circuit 32 includes a metal oxide semiconductor field effect transistor (MOSFET) coupled between a high-potential node and the global bit line GBL. In this example, the transistor receives a voltage from the read control circuit 31 at the gate thereof. The voltage controls the magnitude of the read current Ir. The high-potential node receives the power supply voltage VDD or the internal power supply voltage generated by the voltage generator 18.

The current sink circuit 33 is a circuit that absorbs a current from an interconnect coupled to the current sink circuit 33. The current sink circuit 33 is coupled to the global word line GWL so that it can absorb a current from the global word line GWL. The current sink circuit 33 operates under the control of the read control circuit 31, and is enabled or disabled under the control of the read control circuit 31. In one example, the current sink circuit 33 includes a MOSFET coupled between the global word line GWL and a node that receives the ground voltage VSS. In this example, the transistor receives a control signal from the read control circuit 31 at the gate thereof. The control signal turns on or turns off the transistor.

The coupling circuit 36 is a circuit that connects the global bit line GBL to a dynamically selected one of nodes N1 and N2. The coupling circuit 36 operates under the control of the read control circuit 31. In one example, the coupling circuit 36 includes a switch circuit coupled between the global bit line GBL and the node N1 and a switch circuit coupled between the global bit line GBL and the node N2. In one example, each of the switch circuits includes a p-type MOSFET and an n-type MOSFET which are coupled in parallel to receive logical signals inverted to each other at their respective gates.

While the node N1 is electrically floating, the charge storage circuit 37 stores the charge accumulated in the node N1 at the start of the floating and thus the potential of the node N1 at the start of the floating. In one example, the charge storage circuit 37 includes a capacitor coupled between node N1 and the node of the ground voltage VSS.

While the node N2 is electrically floating, the charge storage circuit 38 stores the charge accumulated in the node N2 at the start of the floating and thus the potential of the node N2 at the start of the floating. In one example, the charge storage circuit 38 includes a capacitor coupled between the node N2 and the node of the ground voltage VSS.

The sense amplifier circuit 39 is a circuit that outputs a signal Dout based on the comparison between the potential of the node N1 and that of the node N2. If the potentials of the nodes N1 and N2 are substantially the same, that is, a difference between the potentials of the nodes N1 and N2 falls within a certain range, the signal Dout has a level indicating the same. If the potentials of the nodes N1 and node N2 are different, that is, a difference in potential between the nodes N1 and N2 exceeds a certain range, the signal Dout has a level indicating the same.

The read control circuit 31 is a circuit that controls the entire data read. The data read includes a step of writing data, as will be described below. The read control circuit 31 instructs the write control circuit 41 to write necessary data during the data write included in the data read. The write control circuit 41 is included in the write circuit 16 as will be described later.

FIG. 8 illustrates an example of components and coupling of the components of a write circuit of the memory device of the first embodiment. As illustrated in FIG. 8, the write circuit 16 includes the write control circuit 41, a write current circuit 42, a current sink circuit 43, and coupling circuits 44 and 45.

The write current circuit 42 is a circuit that supplies a current to a current path including an interconnect coupled to the write current circuit 42. The write current circuit 42 is coupled to a node N3 to allow a write current of a fixed magnitude to be supplied to a current path including the node N3. The write current circuit 42 supplies a dynamically selected one of a plurality of constant currents of different magnitudes. The write current circuit 42 can supply the P write current Iwp and the AP write current Iwap. The write current circuit 42 can supply an AP write current Iwap_1 that is slightly larger than the AP write current Iwap. The write current circuit 42 can also supply an AP write current Iwap_A for each case of A, where A is an integer of two or more. The AP write current Iwap_A is slightly larger than an AP write current Iwap_A−1. The write current circuit 42 operates under the control of the read control circuit 31. The write current circuit 42 supplies the P write current Iwp and one of the AP write currents Iwap, Iwap_1 and Iwap_A−1 under the control of the read control circuit 31. The write current circuit 42 supplies the AP write current Iwap to the node N1 over a dynamically variable period of time under the control of the read control circuit 31.

In one example, the write current circuit 42 includes a MOSFET coupled between a high-potential node and the node N3. In this example, the transistor receives a voltage from the write control circuit 41 at the gate thereof. The voltage controls the magnitude of the current supplied by the write current circuit 42. The high-potential node receives the power supply voltage VDD or an internal power supply voltage generated by the voltage generator 18.

The current sink circuit 43 is a circuit that absorbs a current from an interconnect coupled to the current sink circuit 43. The current sink circuit 43 is coupled to a node N4 and can absorb a current from the node N4. The current sink circuit 43 operates under the control of the write control circuit 41 and is enabled or disabled under the control of the write control circuit 41. In one example, the current sink circuit 43 includes a MOSFET coupled between the node N4 and a node that receives the ground voltage VSS. In this example, the transistor receives a control signal from the write control circuit 41 at the gate thereof. The control signal turns on or turns off the transistor.

The coupling circuit 44 is a circuit that couples a dynamically selected one of the nodes N3 and N4 to the global bit line GBL. The coupling circuit 44 operates under the control of the write control circuit 41. In one example, the coupling circuit 44 includes a switch circuit coupled between the node N3 and the global bit line GBL and a switch circuit coupled between the node N4 and the global bit line GBL.

The coupling circuit 45 is a circuit that couples a dynamically selected one of the nodes N3 and N4 to the global word line GWL. The coupling circuit 45 operates under the control of the write control circuit 41. In one example, the coupling circuit 45 includes a switch circuit coupled between the node N3 and the global word line GWL and a switch circuit coupled between the node N4 and the global word line GWL.

The current sink circuit 43 may be common to the current sink circuit 33. In this case, each of the coupling circuits 44 and 45 is coupled to the current sink circuit 33.

The write control circuit 41 is a circuit that controls the entire data write. The data write includes a step of reading data, as described below. The write control circuit 41 instructs the read control circuit 31 to read necessary data during the data read included in the data write.

### 1.2. Operation

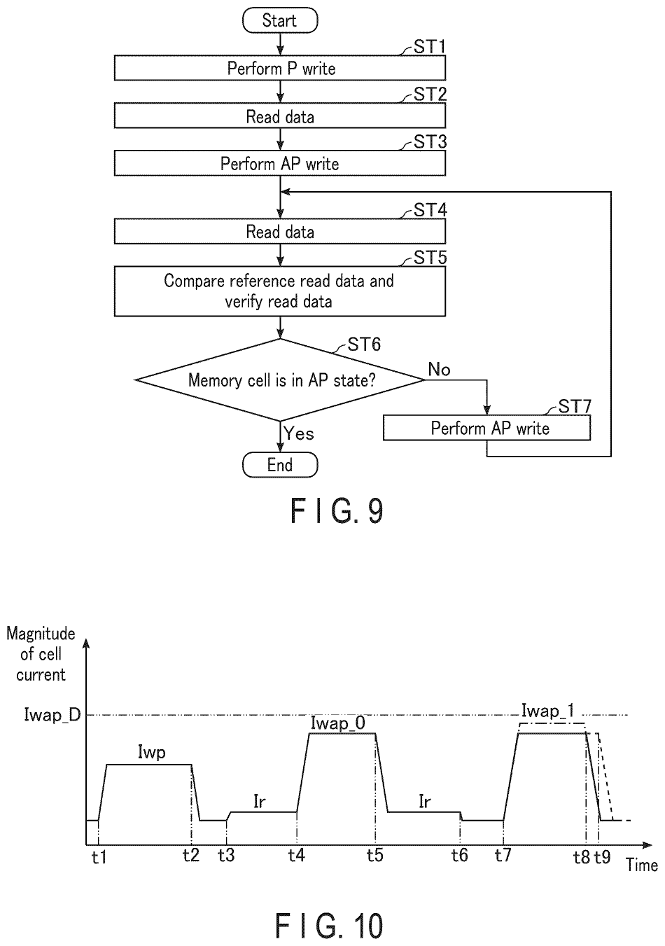

FIG. 9 illustrates a flow of data write to the memory device of the first embodiment. Over the flow of FIG. 9, a single data write target memory cell MC is coupled to the global word line GWL and the global bit line GBL via the row selection circuit 14 and the column selection circuit 15. Hereinafter, the data write target memory cell MC may be referred to as a selected memory cell MC_s. The flow of FIG. 9 starts when the write circuit 16 determines to write “1” data to the selected memory cell MC_s upon receipt of a command or the like, that is, to set the MTJ element MTJ of the selected memory cell MC_s in a high resistance state.

As illustrated in FIG. 9, the write control circuit 41 performs P write to the selected memory cell MC_s (step ST1). For the execution of step ST1, the write control circuit 41 controls the write current circuit 42, current sink circuit 43 and coupling circuits 44 and 45 to cause the P write current Iwp to flow through the selected memory cell MC_s. That is, the write current circuit 42 is coupled to the global bit line GBL via the coupling circuit 44, and the current sink circuit 43 is coupled to the global word line GWL via the coupling circuit 45. In this state, the write control circuit 41 enables the current sink circuit 43 and causes the P-write current Iwp to flow through the write current circuit 42. Hereinafter, the P write in step ST1 may be referred to as reference data write.

The write control circuit 41 reads data from the selected memory cell MC_s (step ST2). For the execution of step ST2, the write control circuit 41 instructs the read control circuit 31 to read data. Upon receipt of the instruction, the read control circuit 31 controls the read current circuit 32 and the current sink circuit 33 to read data. That is, the read control circuit 31 enables the current sink circuit 33 and causes the read current circuit 32 to pass the read current Ir to flow. As the read current Ir flows, a potential the magnitude of which is based on the resistance state of the selected memory cell MC_s is generated in the global bit line GBL.

During the data read in step ST2, the read control circuit 31 controls the coupling circuit 36 to keep the global bit line GBL decoupled from the node N2 and to keep the global bit line GBL coupled to the node N1. Thus, the potential of the global bit line GBL is transferred to the node N1. When the transfer is completed, the read control circuit 31 controls the coupling circuit 36 to decouple the node N1 from the global bit line GBL and electrically float the node N1. As a result, the potential the magnitude of which is based on the resistance state of the selected memory cell MC_s is stored in the node N1 by the charge storage circuit 37. As in step ST2, the data read immediately after the reference data write may be hereinafter referred to as reference data read. In addition, data obtained by the reference data read, that is, charge stored in the charge storage circuit 37 by the reference data read, may be hereinafter referred to as reference read data.

The write control circuit 41 performs AP write to the selected memory cell MC_s (step ST3). For the execution of step ST3, the write control circuit 41 controls the write current circuit 42, current sink circuit 43, and coupling circuits 44 and 45 to cause an AP write current Iwap_0 to flow through the selected memory cell MC_s. That is, the write current circuit 42 is coupled to the global word line GWL via the coupling circuit 45, and the current sink circuit 43 is coupled to the global bit line GBL via the coupling circuit 44. In this state, the write control circuit 41 enables the current sink circuit 43 and causes the write current circuit 42 to pass the AP write current Iwap_0 to flow. The AP write current Iwap_0 is smaller than the AP write current Iwap, more specifically, is smaller than an AP write current Iwap_D that would be used when the first embodiment is not applied. The AP write current Iwap_0 flows over a time period Tw_0.

The write control circuit 41 reads data from the selected memory cell MC_s (step ST4). Step ST4 is the same as step ST2. As a result of step ST2, a potential having a magnitude based on the resistance state of the selected memory cell MC_s is generated in the global bit line GBL.

On the other hand, the potential of the global bit line GBL is stored in the charge storage circuit 38. That is, during the data read in step ST4, the read control circuit 31 controls the coupling circuit 36 to keep the global bit line GBL decoupled from the node N1 and to keep the global bit line GBL coupled to the node N2. Thus, the potential of the global bit line GBL is transferred to the node N2. When the transfer is completed, the read control circuit 31 controls the coupling circuit 36 to decouple the node N2 from the global bit line GBL and electrically float the node N2. Hereinafter, as in step ST4, data read immediately after the AP write (step ST3) may be referred to as verify data read. In addition, hereinafter, data obtained by the verify data read, that is, charge stored in the charge storage circuit 38 by the verify data read may be referred to as verify read data.

The write control circuit 41 compares the reference read data and the verify read data (step ST5). For the execution of step ST5, the write control circuit 41 instructs the read control circuit 31 to start operating the sense amplifier circuit 39. Upon receipt of the instruction, the sense amplifier circuit 39 outputs a signal Dout having a value based on the potentials of the nodes N1 and N2. The signal Dout is received by the write control circuit 41. If the signal Dout indicates that the potentials of the nodes N1 and N2 are substantially the same, it means that the MTJ element MTJ of the selected memory cell MC_s is not in the AP state, that is, the AP write in step ST3 has not been successful. On the other hand, if the signal Dout indicates that the potentials of the nodes N1 and N2 are substantially different, it means that the MTJ element MTJ of the selected memory cell MC_s is in the AP state, that is, the AP write in step ST3 has been successful.

If the signal Dout indicates that the MTJ element MTJ of the selected memory cell MC_s is in the AP state (Yes in step ST6), the write control circuit 41 terminates the flow of FIG. 9. If the signal Dout indicates that the MTJ element MTJ of the selected memory cell MC_s is not in the AP state (No in step ST6), the write control circuit 41 performs further AP write to the selected memory cell MC_s (step ST7).

Step ST7 is substantially the same as step ST3. The difference is the AP write current Iwap to be used and/or a time period over which the AP write current Iwap flows. That is, in one example, the AP write current Iwap_1 may be used in step ST7. The AP write current Iwap_1 is larger than the AP write current Iwap_0. In another example, the AP write current Iwap_0 flows over a time period Tw_1. The time period Tw_1 is longer than a time period Tw_0. The AP write current Iwap_0 may be used.

Step ST7 continues to step ST4. If it is determined in step ST6 subsequent to step ST4 that the MTJ element MTJ of the selected memory cell MC_s is not the AP state, an AP write current Iwap_2 and/or a time period Tw_2 may be used in the subsequent step ST7. The AP write current Iwap_2 is larger than the AP write current Iwap_1. The time period Tw_2 is longer than the time period Tw_1. Similarly, each time step ST7 is executed, if an AP write current Iwap_g was used in the previous step ST7, an AP write current Iwap_g+1 may be used, wherein g is a positive integer. The AP write current Iwap_g+1 is larger than the AP write current Iwap_g. Similarly, each time step ST7 is executed, if a time period Tw_g was used in the previous step ST7, a time period Tw_g+1 may be used. The time period Tw_g+1 is longer than the time period Tw_g.

FIG. 10 illustrates an example of the magnitude of current flowing through a memory cell during AP write to the memory device of the first embodiment along the time axis. The current is a cell current flowing through the selected memory cell MC_s.

As illustrated in FIG. 10, P write current Iwp flows from time t1 to time t2. The period from time t1 to time t2 corresponds to a period of the operation in step ST1 of the flow illustrated in FIG. 9.

Read current Ir flows from time t3 to time t4. The period from time t3 to time t4 corresponds to a period of the operation in step ST2 of the flow illustrated in FIG. 9.

From time t4 to time t5, AP write current Iwap_0 flows. The period from time t4 to time t5 corresponds to a period of the operation in step ST3 of the flow illustrated in FIG. 9.

Read current Ir flows from time t5 to time t6. The period from time t5 to time t6 corresponds to a period of the operation in step ST4 of the flow illustrated in FIG. 9.

No current flows from time t6 to time t7. The period from time t6 to time t7 corresponds to a period of the operation in step ST5 of the flow illustrated in FIG. 9.

The period after time t7 corresponds to the case where the operation of step ST7 in the flow of FIG. 9 is performed. Some of the cases of the operation to be performed as step ST7 are indicated by a solid line, a broken line, and an alternate long and short dashed line. The solid line indicates a case where the same condition as in step ST3 is used in step ST7. As indicated by the solid line, an AP write current Iwap_0 flows from time t7 to time t8.

The broken line indicates a case in which the same AP write current Iwap as the AP write current Iwap used in step ST3 flows for a period that is longer than the period used in step ST3. As indicated by the broken line, the AP write current Iwap_0 flows from time t7 to time t9. Time t9 comes later than time t8.

The alternate long and short dashed line indicates a case in which the AP write current Iwap_1 is used. As indicated by the alternate long and short dashed line, the AP write current Iwap_1 flows from time t7 to time t8.

### 1.3. Advantages (Advantageous Effects)

According to the first embodiment, a memory device including a memory cell having a long lifetime can be provided as described below.

The lifetime of a memory cell depends on the magnitude of a voltage applied to the memory cell and the time over which the voltage is applied. In a memory device including an MTJ element, the highest voltage applied to the MTJ element is generated when an AP write current flows through the MTJ element that is in the AP state. Since the memory device including an MTJ element can overwrite data, the highest voltage is generated when an AP write current is caused to flow through the MTJ element that is already in the AP state, based on write data.

According to the first embodiment, P write is performed and reference read data is acquired, AP write is performed, verify read data is acquired and compared with the reference read data, and if the result of the comparison indicates the P state of the MTJ element, further AP write is performed. The first AP write uses an AP write current Iwap_0 that is smaller than a normal AP write current Iwap_D. Therefore, even if the selected memory cell MC_s is in the AP state, the voltage applied to the selected memory cell MC_s by the first AP write is lower than the voltage in the case of using the AP write current Iwap_D. Thus, the application of a high voltage to the MTJ element MTJ is suppressed, and in turn the deterioration of the lifetime of the MTJ element MTJ and consequently the memory cell MC.

The AP write current Iwap_0 is smaller than the AP write current Iwap_D. Thus, the use of the AP write current Iwap_0 makes it harder to bring the MTJ element MTJ into the AP state than the use of the AP write current Iwap_D. However, further AP write is performed if the resistance state of the MTJ element MTJ of the selected memory cell MC_s is determined to be in a P state after AP write using the AP write current Iwap_0. Therefore, even if the MTJ element MTJ is in the P state after the AP write using the AP write current Iwap_0, the MTJ element MTJ can be brought into the AP state.

### 2. Second Embodiment

### 2.1. Configuration

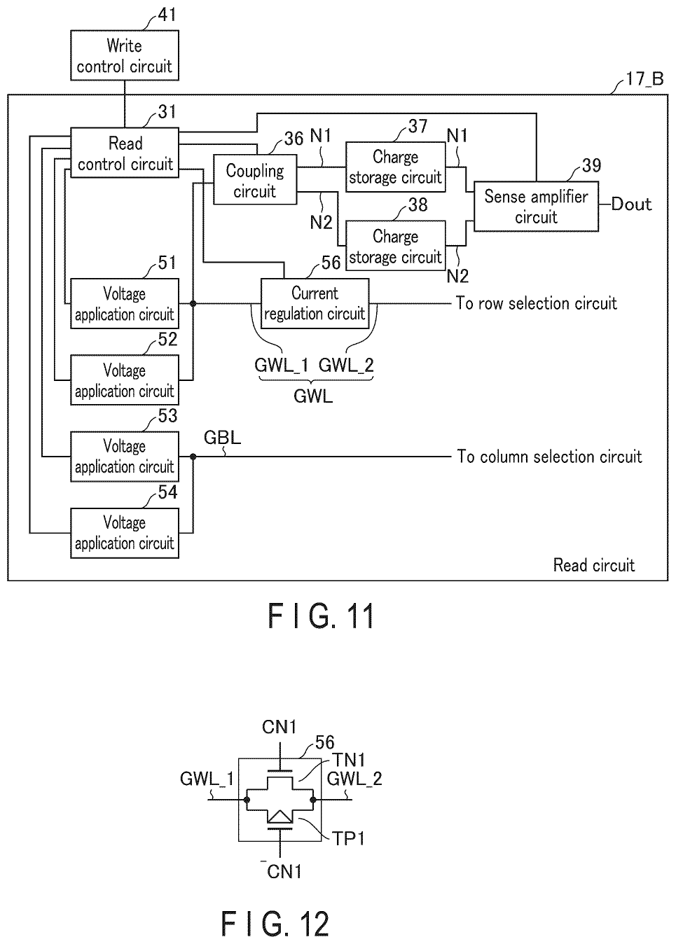

FIG. 11 illustrates a first example of components and coupling of the components of a read circuit of the memory device of a second embodiment. As illustrated in FIG. 11, the read circuit 17_B of the memory device 1_B of the second embodiment does not include the read current circuit 32 or the current sink circuit 33 of the first embodiment, but includes voltage application circuits 51, 52, 53 and 54, and a current regulation circuit 56.

The voltage application circuit 51 is a circuit that applies a voltage to a node coupled to the voltage application circuit 51. The voltage application circuit 51 is coupled to a global word line GWL_1 to apply a precharge voltage VPRCH to the global word line GWL_1. The global word line GWL_1 is part of the global word line GWL. In one example, the precharge voltage VPRCH has a fixed magnitude and is higher than the ground voltage VSS. The voltage application circuit 51 is disabled or enabled under the control of the read control circuit 31. The voltage application circuit 51 applies a precharge voltage VPRCH to the global word line GWL_1 while it is enabled. The precharge voltage VPRCH is supplied from a voltage generator 18. In one example, the voltage application circuit 51 includes a switch circuit coupled between a node that receives the precharge voltage VPRCH and the global word line GWL.

The voltage application circuit 52 is a circuit that applies a voltage to a node coupled to the voltage application circuit 52. The voltage application circuit 52 is coupled to the global word line GWL_1 to apply a non-selected voltage VUSEL to the global word line GWL. In one example, the non-selected voltage VUSEL has a fixed magnitude and has a magnitude between the precharge voltage VPRCH and the ground voltage VSS. The non-selected voltage VUSEL is supplied from the voltage generator 18. The voltage application circuit 52 is disabled or enabled under the control of the read control circuit 31. The voltage application circuit 52 applies the non-selected voltage VUSEL to the global word line GWL_1 while it is enabled. In one example, the voltage application circuit 52 includes a switch circuit coupled between a node that receives the non-selected voltage VUSEL and the global word line GWL_1.

The voltage application circuit 53 is a circuit that applies a voltage to a node coupled to the voltage application circuit 53. The voltage applying circuit 53 is coupled to a global bit line GBL to apply the non-selected voltage VUSEL to the global bit line GBL. The voltage application circuit 53 is disabled or enabled under the control of the read control circuit 31. The voltage application circuit 53 applies the non-selected voltage VUSEL to the global bit line GBL while it is enabled. In one example, the voltage application circuit 53 includes a switch circuit coupled between a node that receives the non-selected voltage VUSEL and the global bit line GBL.

The voltage application circuit 54 is a circuit that applies a voltage to a node coupled to the voltage application circuit 54. The voltage application circuit 54 is coupled to the global bit line GBL to apply the ground voltage VSS to the global bit line GBL. The voltage application circuit 54 is disabled or enabled under the control of the read control circuit 31. The voltage application circuit 54 applies the ground voltage VSS to the global bit line GBL while it is enabled. In one example, the voltage application circuit 54 includes a switch circuit coupled between global bit line GBL and a node that receives the ground voltage VSS.

The current regulation circuit 56 is a circuit that regulates the magnitude of current flowing through the global word line GWL. The current regulation circuit 56 regulates the magnitude of current flowing into the global word line GWL_1 and supplies the regulated current to a global word line GWL_2. The global word line GWL_2 is part of the global word line GWL.

FIG. 12 illustrates a first example of the components and coupling of the components of a current regulation circuit of the memory device of the second embodiment. As illustrated in FIG. 12, the current regulation circuit 56 includes an n-type MOSFET TN1 and a p-type MOSFET TP1. The transistors TN1 and TP1 are coupled in parallel between the global word lines GWL_1 and GWL_2. The transistor TN1 receives a control signal CN1 at the gate thereof. The transistor TP1 receives a control signal ⁻CN1 at the gate thereof. The symbol “⁻” indicates the inversion of the logic of a signal whose name is not accompanied by the symbol “⁻”. The control signals CN1 and ⁻CN1 are supplied from the read control circuit 31.

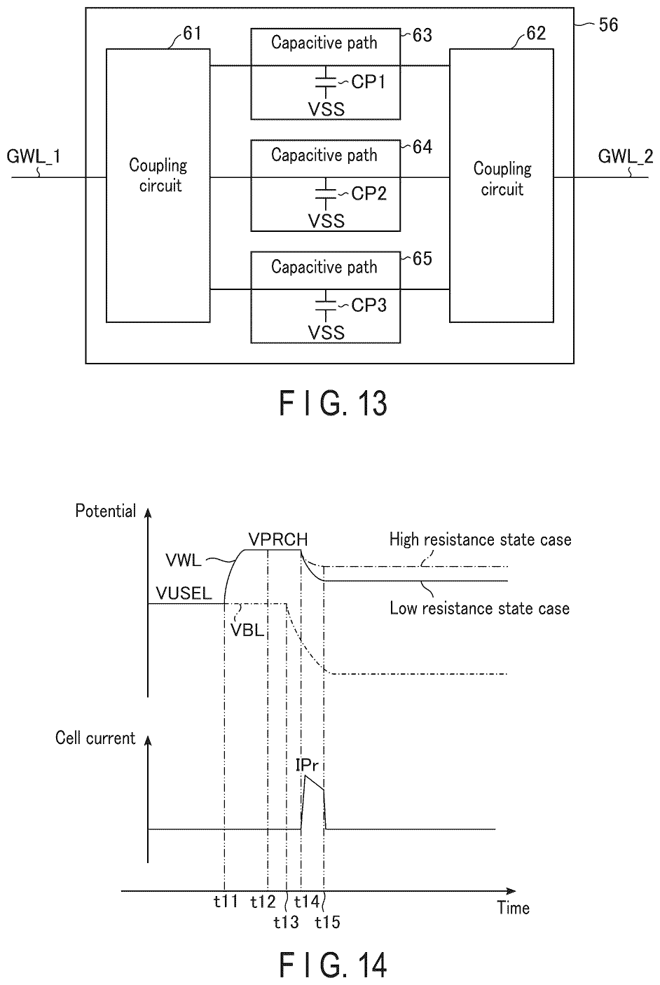

FIG. 13 illustrates a second example of the components and coupling of the components of the current regulation circuit of the memory device of the second embodiment. As illustrated in FIG. 13, the current regulation circuit 56 includes coupling circuits 61 and 62 and capacitive paths 63, 64 and 65.

The coupling circuit 61 is a circuit that couples the global word line GWL_1 to a dynamically selected one of the capacitive paths 63, 64 and 65. The coupling circuit 61 operates under the control of the read control circuit 31. In one example, the coupling circuit 61 includes a switch between the global word line GWL_1 and the capacitive path 63, a switch between the global word line GWL_1 and the capacitive path 64, and a switch between the global word line GWL_1 and the capacitive path 65.

The coupling circuit 62 is a circuit that couples a dynamically selected one of the capacitive paths 63, 64 and 65 to the global word line GWL_2. The coupling circuit 62 operates under the control of the read control circuit 31. In one example, the coupling circuit 62 includes a switch between the capacitive path 63 and the global word line GWL_2, a switch between the capacitive path 64 and the global word line GWL_2, and a switch between the capacitive path 65 and the global word line GWL_2.

The capacitive path 63 is a path which electrically couples the coupling circuits 61 and 62 and which has capacitance. The capacitive path 63 adds capacitance EC1 to the global word line GWL while being coupled to the global word lines GWL_1 and GWL_2 via the coupling circuits 61 and 62. In one example, the capacitive path 63 includes a conductor coupled to the coupling circuits 61 and 62 and a capacitance element CP1 coupled between the conductor and a node that receives the ground voltage VSS. The capacitance element CP1 has a capacitance EC1. Examples of the capacitance element CP1 include a capacitive element and parasitic capacitance.

The capacitive path 64 is a path which electrically couples the coupling circuits 61 and 62 electrically and which has capacitance. The capacitive path 64 adds a capacitance EC2 to the global word line GWL while being coupled to the global word lines GWL_1 and GWL_2 via the coupling circuits 61 and 62. The capacitance EC2 is larger than the capacitance EC1. In one example, the capacitive path 64 includes a conductor coupled to the coupling circuits 61 and 62 and a capacitance element CP2 coupled between the conductor and a node that receives the ground voltage VSS. The capacitance element CP2 has the capacitance EC2. Examples of the capacitance element CP2 include a capacitive element and parasitic capacitance.

The capacitive path 65 is a path which electrically couples the coupling circuits 61 and 62 electrically and which has capacitance. The capacitive path 65 adds capacitance EC3 to the global word line GWL while being coupled to the global word lines GWL_1 and GWL_2 via the coupling circuits 61 and 62. The capacitance EC3 is larger than the capacitance EC2. In one example, the capacitive path 65 includes a conductor coupled to the coupling circuits 61 and 62 and a capacitance element CP3 coupled between the conductor and a node that receives the ground voltage VSS. The capacitance element CP3 has the capacitance EC3. Examples of the capacitance element CP3 include a capacitive element and parasitic capacitance.

### 2.2. Operation

FIG. 14 illustrates the potentials of some nodes along the time axis during data read in the memory device of the second embodiment.

Over the time period illustrated in FIG. 14, a single selected memory cell MC_s is coupled to the global word line GWL and the global bit line GBL via the row selection circuit 14 and the column selection circuit. Thus, the bit line BL coupled to the selected memory cell MC_s has a potential that follows the potential of the global bit line GBL. The word line WL coupled to the selected memory cell MC_s has a potential that follows the potential of the global word line GWL. Hereinafter, the potential of the global bit line GBL may also be referred to as a global bit line potential VBL and the potential of the global word line GWL may also be referred to as a global word line potential VWL.

At the beginning of the time period illustrated in FIG. 14, the global bit line potential VBL and the global word line potential VWL have a non-selected potential VUSEL. This can occur when the voltage application circuits 51 and 54 are disabled and the voltage application circuits 52 and 53 are enabled. The non-selected potential VUSEL is a potential having a magnitude that an interconnect has when the non-selected voltage VUSEL is applied, and in one example, has substantially the same magnitude as that of the non-selected voltage VUSEL.

At time t11, the global word line potential VWL has a precharge potential VPRCH. This can occur when the voltage application circuit 52 is disabled and the voltage application circuit 51 is enabled. The precharge potential VPRCH is a potential having a magnitude that an interconnect has when the precharge voltage VPRCH is applied, and in one example, has substantially the same magnitude as that of the precharge voltage VPRCH.

At time t12, the global word line potential VWL is being electrically floated. This can occur when the voltage application circuits 51 and 52 are both disabled.

At time t13, the global bit line potential VBL has a ground potential VSS. This can occur when the voltage application circuit 53 is disabled and the voltage application circuit 54 is enabled. The ground potential VSS is a potential having a magnitude that an interconnect has when the ground voltage VSS is applied, and in one example, has substantially the same magnitude as that of the ground voltage VSS.

The global bit line potential VBL decreases from time t13 and thus, at time t14, a difference between the global word line potential VWL and the global bit line potential VBL reaches a threshold voltage Vth. Accordingly, the switching element SE of the selected memory cell MC_s is on. Thus, the global word line GWL is electrically coupled to the global bit line GBL via the switching element SE that is turned on in the selected memory cell MC_s. Therefore, a cell current flows from the global word line GWL toward the global bit line GBL. The cell current has a peak value IPr.

Since the global word line GWL electrically floats, the global word line potential VWL lowers as a cell current flows. During this time, the global word line potential VWL lowers at different speeds based on the state of the MTJ element MTJ of the selected memory cell MC_s. The global word line potential VWL when the MTJ element MTJ of the selected memory cell MC_s is in a high resistance state lowers more slowly than the global word line potential VWL when the MTJ element MTJ of the selected memory cell MC_s is in a low resistance state.

At time t15, the global word line potential VWL has a magnitude that is based on the resistance state of the MTJ element MTJ of the selected memory cell MC_s. That is, as the global word line potential VWL lowers, a difference between the global word line potential VWL and the global bit line potential VBL is lessened. If, therefore, the terminal voltage of the selected memory cell MC_s reaches a certain value based on the resistance state of the MTJ element MTJ of the selected memory cell MC_s, the switching element SE of the selected memory cell MC_s is turned off. As a result, the global word line potential VWL stops decreasing and thus has a certain magnitude.

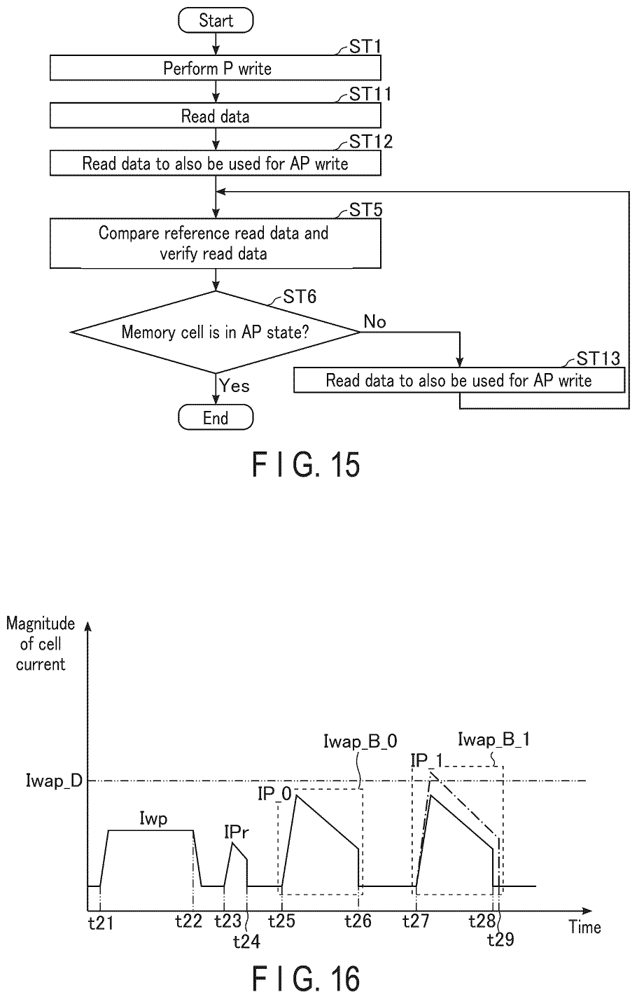

FIG. 15 illustrates a flow of data write to the memory device of the second embodiment. Over the flow of FIG. 15, a selected memory cell MC_c is coupled to the global word line GWL and the global bit line GBL via the row selection circuit 14 and the column selection circuit 15. The flow of FIG. 15 starts when the write circuit 16 determines to write “1” data to the selected memory cell MC_s upon receipt of a command or the like, that is, to bring the MTJ element MTJ of the selected memory cell MC_s into a high resistance state.

As illustrated in FIG. 15, step ST1 is executed.

The write control circuit 41 reads data from the selected memory cell MC_s (step ST11). Step ST11 corresponds to reference data reading. For the execution of step ST11, the write control circuit 41 instructs the read control circuit 31 to read data. Upon receiving the instruction, the read control circuit 31 performs the operation which is described above with reference to FIG. 14 to read data. As a cell current having a peak value IPr flows, a potential having a magnitude based on the resistance state of the MTJ element MTJ of the selected memory cell MC_s is generated on the global bit line GBL.

During the data reading, the write control circuit 41 instructs the read control circuit 31 to limit the upper limit of current flowing out of the global word line GWL_2 from time t13 in FIG. 14 to the upper limit IUL_0 under the control of the current regulation circuit 56. In the example shown in FIG. 12, based on the instruction, the read control circuit 31 controls the magnitudes of the control signals CN and ⁻CN to regulate the currents flowing through the transistors TN1 and TP1. In the example illustrated in FIG. 13, upon receiving the instruction, the read control circuit 31 controls the coupling circuits 61 and 62 to couple the global word lines GWL_1 and GWL_2 via the capacitive path 63.

In addition, under the same control as that in step ST2 during step ST11, the charge storage circuit 37 stores reference read data at the node N1.

The write control circuit 41 performs AP write and data read to and from the selected memory cell MC_s in parallel (step ST12). The data read in step ST12 corresponds to the verify data read. For the execution of step ST12, the write control circuit 41 instructs the read control circuit 31 to read data. Upon receiving the instruction, the read control circuit 31 performs the operation which is described above with reference to FIG. 14 to read data.

During the data read, the write control circuit 41 instructs the read control circuit 31 to limit the upper limit of the current flowing out of the global word line GWL_2 from time t13 in FIG. 14 to the upper limit IUL_1 under the control of the current regulation circuit 56. The upper limit IUL_1 is greater than the upper limit IUL_0. In the example illustrated in FIG. 12, upon receipt of the instruction, the read control circuit 31 controls the magnitudes of the control signals CN and ⁻CN to form a state in which a current whose magnitude is larger than that of the current that can flow through the transistors TN1 and TP1 in the reference data read in step ST11 can flow through the transistors TN1 and TP1. In the example illustrated in FIG. 13, upon receipt of the instruction, the read control circuit 31 controls the coupling circuits 61 and 62 to couple the global word lines GWL_1 and GWL_2 via the capacitive path 64. Thus, during the data read, the global word line GWL has a capacity that is larger than that added to the global word line GWL during the (reference) data read (step ST11). Thus, a large amount of electric charge is stored in the global word line GWL immediately before the global word line GWL is electrically floated at time t12. Therefore, a large amount of cell current flows through the selected memory cell MC_s from time t13.

As the cell current flows, a potential having a magnitude based on the resistance state of the MTJ element MTJ of the selected memory cell MC_s is generated on the global bit line GBL.

In addition, under the same control as that in step ST4 during step ST12, the charge storage circuit 38 stores verify read data at the node N1.

During data read, under the control of the current regulation circuit 56, the cell current flowing through the selected memory cell MC_s from time t13 is larger than the cell current flowing through the selected memory cell MC_s in step ST11. This cell current functions as an AP write current Iwap_B_0 and causes an AP write to the selected memory cell MC_s. The AP write current Iwap_B_0 has a peak value IP_0 of a certain magnitude. The peak value IP_0 is larger than the peak value IPr. The peak value IP_0 may be equal to the AP write current Iwap or may be smaller than the AP write current Iwap. In one example, the peak value IP_0 is smaller than the AP write current Iwap. The AP write current Iwap_B_0 flows over a time period Tw_B_0.

In a case of the configuration of the current regulation circuit 56 illustrated in FIG. 12, the control signals CN and ⁻CN have a magnitude which does not allow the AP write current Iwap_B_0 to flow but does allow the cell current of the peak value IPr to flow from t13 during the operation of step ST2. The control signals CN and ⁻CN also have a magnitude which allows the AP write current Iwap_B_0 to flow from time t13 during the operation of step ST12.

In a case of the configuration of the current regulation circuit 56 illustrated in FIG. 13, the capacitance element CP2 of the capacitive path 64 has a capacity that allows an amount of charge to be stored in the global word line GWL that allows the AP write current Iwap_B_0 of the peak value IP_0 to flow in step ST12.

As is described above with reference to FIG. 5, the switching element SE turns off depending upon the terminal voltage of the MTJ element MTJ. If, therefore, regardless of the magnitude of the cell current, the terminal voltage of the selected memory cell MC_s reaches a specific magnitude based on the resistance state of the MTJ element MTJ of the selected memory cell MC_s, the switching element SE of the selected memory cell MC_s turns off. The flow of a cell current having a sufficient magnitude for AP writing does not affect data reading. Step ST12 continues to step ST5.

If the MTJ element MTJ of the selected memory cell MC_s is in the AP state (Yes in step ST6), the write control circuit 41 terminates the flow of FIG. 15. If the MTJ element MTJ of the selected memory cell MC_s is not in the AP state (No in step ST6), the write control circuit 41 performs further AP write to the selected memory cell MC_s (step ST13).

Step ST13 is substantially the same as step ST12. The difference between them is the AP write current Iwap_B used and/or the time for which the AP write current Iwap_B is caused to flow. That is, in one example, AP write current Iwap_B_1 may be used in step ST13. The AP write current Iwap_B_1 has a peak value IP_1. The peak value IP_1 is larger than the peak value IP_0 of the AP write current Iwap_B_0. In another example, the AP write current Iwap_B_0 flows over a time period Tw_B_1. The time period Tw_B_1 is longer than the time period Tw_B_0.

The magnitude of the peak value IP of the AP write current Iwap_B and/or the time for which the AP write current Iwap_B is caused to flow may be adjusted by selecting one of the capacitive paths 63, 64 and 65. Additional capacitive paths are provided in order to cause AP write currents Iwap_B having a larger number of different magnitude peak values IP to flow. The additional capacitive paths have a capacity that is larger than the capacitance element CP3.

Step ST13 continues to step ST5. If it is determined in step ST6 subsequent to step ST5 that the MTJ element MTJ of the selected memory cell MC_s is not in the AP state, the AP write current Iwap_2 with the peak value IP_2 and/or the time period Tw_B_2 may be used in the subsequent step ST13. The peak value IP_2 is larger than the peak value IP_1 of the AP write current Iwap_B_1. The time period Tw_B_2 is longer than the time period Tw_B_1. Similarly, each time step ST13 is executed, if an AP write current Iwap_B_g having a peak value IP_g was used in the previous step ST13, an AP write current Iwap_B_g+1 having a peak value IP_g+1 may be used. The peak value IP_g+1 is larger than the peak value IP_g. Similarly, each time step ST13 is executed, if a time period Tw_B_g was used in the previous step ST13, a time period Tw_B_g+1 may be used. The period Tw_B_g+1 is longer than the time period Tw_B_g.

FIG. 16 illustrates an example of the magnitude of current flowing through a memory cell during AP write to the memory device of the second embodiment along the time axis. The current is a cell current flowing through the selected memory cell MC_s.

As illustrated in FIG. 16, P write current Iwp flows from time t21 to time t22. The period from time t21 to time t22 corresponds to the period for which the operation of step ST1 in the flow of FIG. 15 is performed.

From time t23 to time t24, a read current having a peak value IPr flows. The period from time t23 to time t24 corresponds to the period for which the operation of step ST11 in the flow of FIG. 15 is performed.

From time t25 to time t26, an AP write current Iwap_B_0 having a peak value IP_0 flows. The period from time t25 to time t26 corresponds to the period of step ST12 in the flow of FIG. 15.

No current flows from time t26 to time t27. The period from time t26 to time t27 corresponds to the period for which the operation of step ST5 in the flow of FIG. 15 is performed.

The period after time t27 corresponds to the case where the operation of step ST13 in the flow of FIG. 15 is performed. Some of the cases of the operation to be performed as step ST13 are indicated by a solid line and an alternate long and short dashed line. The solid line indicates a case where the same condition as in step ST12 is used in step ST13. As indicated by the solid line, an AP write current Iwap_B_0 having a peak value IP_0 flows from time t27 to time t28.

The alternate long and short dashed line indicates a case where an AP write current Iwap_B_1 is used. As indicated by the alternate long and short dashed line, the AP write current Iwap_B_1 having a peak value IP_1 is caused to flow from time t27 to time t29.

### 2.3. Advantages

According to the second embodiment, as in the first embodiment, P write is performed and reference read data is acquired, AP write is performed, verify read data is acquired and compared with the reference read data, and if the result of the comparison indicates the P state of the MTJ element, further AP write is performed. Therefore, the same advantages as those of the first embodiment can be obtained.

According to the second embodiment, data is read using a low hold voltage VhdL and a high hold voltage VhdH which are obtained in the process of lowering the terminal voltage of the selected memory cell MC_s, and the data read and AP write are performed through a single operation. The data read using the low hold voltage VhdL and high hold voltage VhdH employs a phenomenon in which the switching element SE turns off based on the resistance state of the MTJ element MTJ of the selected memory cell MC_s, with the result that the control of application of current to the selected memory cell MC_s is simplified. Since the data read and AP write are performed through a single operation, the entire AP write is completed in a short time.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a memory cell including a magnetoresistance effect element and a switching element coupled to the magnetoresistance effect element;
a first interconnect coupled to a first end of the memory cell; and
a second interconnect coupled to a second end of the memory cell,
wherein:
an operation of bringing the magnetoresistance effect element into a first resistance state includes a first period, a second period after the first period, a third period after the second period, a fourth period after the third period, and a fifth period after the fourth period;
in the first period, a first operation is performed to bring the magnetoresistance effect element into a second resistance state exhibiting a resistance that is lower than a resistance of the first resistance state;
in the second period, first data is acquired based on a resistance state of the magnetoresistance effect element;
in the third period, a second operation is performed to bring the magnetoresistance effect element into the first resistance state;
in the fourth period, second data is acquired based on the resistance state of the magnetoresistance effect element; and
in the fifth period, a third operation is performed to bring the magnetoresistance effect element into the first resistance state.

2. The memory device of claim 1, wherein the third operation is performed if the magnetoresistance effect element is not in the first resistance state.

3. The memory device of claim 1, wherein the third operation is performed if the magnetoresistance effect element is not in the first resistance state based on the first data and the second data.

4. The memory device of claim 1, wherein:
the second operation includes causing a first current to flow through the memory cell in a first direction; and
the third operation includes causing a second current that is larger than the first current to flow through the memory cell MC in the first direction.

5. The memory device of claim 4, wherein the first operation includes causing a third current to flow through the memory cell in a second direction opposite to the first direction.

6. The memory device of claim 1, wherein:
the second operation includes causing a first current to flow through the memory cell MC in a first direction over a sixth period; and
the third operation includes causing the first current to flow through the memory cell in the first direction over a seventh period that is longer than the sixth period.

7. The memory device of claim 6, wherein the first operation includes causing a second current to flow through the memory cell in a second direction opposite to the first direction.

8. The memory device of claim 1, wherein:
the first data is based on a potential generated in the second interconnect when the memory cell is supplied with a current; and
the second data is based on a potential generated in the second interconnect when the memory cell is supplied with a current.

9. A memory device comprising:
a memory cell including a magnetoresistance effect element and a switching element coupled to the magnetoresistance effect element;
a first interconnect coupled to a first end of the memory cell; and
a second interconnect coupled to a second end of the memory cell,
wherein:
an operation of bringing the magnetoresistance effect element into a first resistance state includes a first period, a second period after the first period, a third period after the second period, and a fourth period after the third period;
in the first period, a first operation is performed to bring the magnetoresistance effect element into a second resistance state exhibiting a resistance that is lower than a resistance of the first resistance state;
in the second period, a second operation is performed to acquire first data based on a resistance state of the magnetoresistance effect element;
in the third period, a third operation is performed to bring the magnetoresistance effect element into the first resistance state and to acquire second data based on a resistance state of the magnetoresistance effect element; and
in the fourth period, a fourth operation is performed to bring the magnetoresistance effect element into the first resistance state.

10. The memory device of claim 9, wherein the third operation is performed if the magnetoresistance effect element is not in the first resistance state.

11. The memory device of claim 10, wherein the third operation is performed if the magnetoresistance effect element is not in the first resistance state based on the first data and the second data.

12. The memory device of claim 9, wherein:
the third operation includes causing a first current having a first peak value to flow through the memory cell in a first direction; and
the fourth operation includes causing a second current having a second peak value that is larger than the first peak value to flow through the memory cell in the first direction.

13. The memory device of claim 12, wherein the first operation includes causing a third current to flow through the memory cell in a second direction opposite to the first direction.

14. The memory device of claim 12, wherein:
the third operation includes causing a first current to flow through the memory cell MC in a first direction over a fifth period; and
the fourth operation includes causing the first current to flow through the memory cell in the first direction over a sixth period that is longer than the fifth period.

15. The memory device of claim 9, wherein the first operation includes causing a second current to flow through the memory cell in a second direction opposite to the first direction.

16. The memory device of claim 9, wherein:
the third operation includes:
applying a first voltage to the first interconnect;
floating the first interconnect electrically after the first voltage is applied to the first interconnect; and
applying a second voltage that is lower than the first voltage to the second interconnect while the first interconnect is electrically being floated; and
the second data is based on a potential generated in the first interconnect after the second voltage is applied to the second interconnect.

17. The memory device of claim 16, wherein the fourth operation includes:
applying a first voltage to the first interconnect;
floating the first interconnect electrically after the first voltage is applied to the first interconnect; and
applying the second voltage to the second interconnect while the first interconnect is electrically being floated.

18. The memory device of claim 16, wherein the second operation includes:
applying the first voltage to the first interconnect;
floating the first interconnect electrically after the first voltage is applied to the first interconnect; and
applying the second voltage to the second interconnect while the first interconnect is electrically being floated.

19. The memory device of claim 9, wherein:
the first interconnect includes a path that causes a current having an upper limit of a first value to flow during the second operation; and
the first interconnect includes a path that causes a current having an upper limit of a second value that is larger than the first value to flow during the third operation.

20. The memory device of claim 9, wherein:
the first interconnect has a first capacity during the second operation; and
the first interconnect has a second capacitance that is larger than the first capacity during the third operation.
